(19) United States
(12) Patent Application Publication
(10) Pub. No.: US 2026/0136944 A1
(43) Pub. Date: May 14, 2026

(54) POWER SUPPLY MODULE

(71) Applicant: MetaPWR Electronics Co., Ltd., Shanghai (CN)

(72) Inventors: Shouyu HONG, Shanghai (CN); Hongxiu Liu, Shanghai (CN); Xiaoni Xin, Shanghai (CN); Mingzhun ZHANG, Shanghai (CN); Jianhong ZENG, Shanghai (CN)

(73) Assignee: MetaPWR Electronics Co., Ltd., Shanghai (CN)

(21) Appl. No.: 19/389,026

(22) Filed: Nov. 14, 2025

(30) Foreign Application Priority Data
Nov. 14, 2024 (CN) 202411627854.2

(51) Int. Cl. H01L 23/64; H01L 23/498; H01L 23/538; H01L 25/18; H03K 17/08

(52) U.S. Cl. CPC H10W 44/501; H03K 17/08; H10W 70/611; H10W 70/635; H10W 70/65; H10W 70/66; H10W 90/00; H03K 2017/0806

(57) ABSTRACT

A power supply module including a substrate, a magnetic assembly, and an element layer is provided. The magnetic assembly is arranged above a semiconductor switching device, and a common end of the semiconductor switching device is arranged on an upper surface of the switching device and is connected to a winding of the magnetic assembly. The element layer includes an insulator, at least one power chip, a capacitor, a connector, and an upper surface and a lower surface opposite to each other. A laminated wiring is used inside the substrate, and the input capacitor is integrated, and the input capacitor is connected in parallel with the semiconductor switching devices electrically connected in series, thereby reducing the input loop and reducing the parasitic inductance in the input loop.

### CROSS-REFERENCE TO RELATED APPLICATION

This application claims the priority benefit of China application serial no. 202411627854.2 filed on Nov. 14, 2024. The entirety of the above-mentioned patent application is hereby incorporated by reference herein and made a part of this specification.

### BACKGROUND

### Description of Related Art

In recent years, with the increasing demand of various types of artificial intelligence and data processing, the global energy consumption of computing power presents explosive growth. Moreover, due to the increasing power consumption of these computing power units, limitations on the size are also becoming increasingly demanding; and therefore, the requirements of the occupied area, height, efficiency, heat dissipation, electromagnetic interference, and the like of the power supply module directly supplying power to the computing chip is becoming higher. The power supply modules generally include a magnetic element, an input capacitor, an output capacitor, a power chip, and the like. How to efficiently integrate these components, and satisfy numerous requirements of a system for a power supply, such as reducing conduction impedance, reducing module size, reducing heat transfer thermal resistance, effectively reducing loop inductance of a Vin-GND loop, preventing interference of jump points such as SW on external signals, are critical issues that the researchers in the field must address.

### SUMMARY

In view of the above, one of the objectives of the application is to provide a power supply module with a high heat dissipation and low parasitic inductance, comprising a substrate, a magnetic assembly, and an element layer; the element layer comprises an insulator, at least one power chip, a capacitor, a connector, and an upper surface and a lower surface opposite to each other; the substrate comprises an upper surface and a lower surface opposite to each other, the substrate comprises metal wiring layers and the metal wiring layers are provided on the upper surface and the lower surface of the substrate; the magnetic assembly is provided on the upper surface of the substrate, and winding pins of the magnetic assembly are electrically connected to the metal wiring layer on the upper surface of the substrate;

The power chip comprises a functional surface, at least two planar power devices connected in series are integrated on the functional surface, and the series node is an electrical common terminal; the functional surface of the power chip is provided with a chip pin; the power chip is provided on the lower surface of the substrate, and the chip pin is electrically connected to the metal wiring layer on the lower surface of the substrate; the winding pins of the magnetic assembly are electrically connected to the electrical common end;

Projections of the winding pins of the magnetic assembly and the power chip on the same horizontal plane at least partially overlap;

The capacitor is arranged on the lower surface of the substrate, and the capacitor is connected in parallel with two planar power devices connected in series;

The insulator covers at least a portion of a lower surface of the substrate, the power chip, and the capacitor. The upper surface of the element layer is disposed adjacent to the lower surface of the substrate, the lower surface of the element layer is provided with a surface metal wiring layer, and the connector electrically connects the metal wiring layer of the substrate and the surface metal wiring layer on the lower surface of the element layer.

Preferably, the connector penetrates through the upper surface and the lower surface of the element layer, and the connector is a via or a copper block.

Preferably, a side surface of the substrate and a side surface of the element layer are metallized to form a connector, and the connector covers a part of the upper surface of the substrate, a part of the side surfaces of the substrate and the element layer, and a part of the lower surface of the element layer.

Preferably, the connector adopts a blind hole structure.

Preferably, a size of the magnetic assembly in a horizontal direction is less than a size of the substrate in a horizontal direction; and other component is provided in an area of that the magnetic assembly does not cover the substrate.

Preferably, winding pins of the magnetic assembly protrudes from the lower surface of the magnetic assembly; an accommodating space exists among the lower surface of the magnetic assembly, the upper surface of the substrate and winding pins of the magnetic assembly for accommodating an input capacitor and/or an output capacitor.

Preferably, an input capacitor and the input capacitor and the output capacitor are arranged in the accommodating space, and the negative electrodes of the input capacitor and the output capacitor are arranged on copper laying on the same layer.

Preferably, the upper surface of the substrate is provided with one of the input capacitor and the output capacitor, and the lower surface of the substrate is provided with the other of the input capacitor and the output capacitor; the negative electrodes of the input capacitor and the output capacitor are on the copper laying on the upper surface and the lower surface of the substrate, and projections of the copper layings disposing on the lower surface and the upper surface on the same horizontal plane at least partially overlap, and are connected by means of the vias.

Preferably, a heat dissipation via or a heat dissipation groove is provided between the non-functional surface of the power chip and the lower surface of the element layer.

Preferably, a winding of the magnetic assembly is at least partially exposed on the upper surface of the magnetic assembly.

Preferably, the power supply module, further comprising a dielectric layer and an outer wiring layer, wherein the dielectric layer is disposed between the upper surface of the substrate and the lower surface of the magnetic assembly, and the outer wiring layer is disposed between the dielectric layer and the magnetic assembly; the outer wiring layer is electrically connected to the metal wiring layer on the upper surface of the substrate through a via.

Preferably, the outer wiring layer and the surface metal wiring layer on the lower surface of the element layer are completed in a same process.

Preferably, a dielectric layer and an outer wiring layer are disposed on the lower surface of the element layer, and the outer wiring layer is disposed on a lower surface of the dielectric layer; and the outer wiring layer is electrically connected to the surface metal wiring layer on the lower surface of the element layer through a via.

Compared with the prior art, the application has the following beneficial effects:
(1) The present application provides a power supply module with a high heat dissipation and low parasitic inductance. On the one hand, a magnetic assembly is arranged above a semiconductor switching device, a common end of the semiconductor switching device is arranged on an upper surface of the switching device, and is connected to a winding of the magnetic assembly, thereby reducing the upward thermal resistance of the switching device;
(2) On the other hand, a laminated wiring is used inside the substrate, and the input capacitor is integrated, and the input capacitor is connected in parallel with the semiconductor switching devices electrically connected in series, thereby reducing the input loop and reducing the parasitic inductance in the input loop.

### BRIEF DESCRIPTION OF THE DRAWINGS

FIG. 1 is a Buck circuit topology applicable to a power supply module shown in the present application.

FIG. 2A to FIG. 2F are embodiments of a power supply module.

FIG. 3A to FIG. 3G are extended embodiments of a power supply module.

### DESCRIPTION OF THE EMBODIMENTS

One of the cores of the present application is to provide a power supply module with high heat dissipation and low parasitic inductance. On the one hand, the magnetic assembly is arranged above the semiconductor switching device, and the common end of the semiconductor switching device is arranged on the upper surface of the switching device and is connected to the windings of the magnetic assembly, thereby reducing the upward thermal resistance of the switching device; On the other hand, a laminated wiring is used inside the substrate, and the input capacitor is integrated, and the input capacitor is connected in parallel with the semiconductor switching device electrically connected in series, so as to reduce the input loop and reduce the parasitic inductance in the input loop.

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

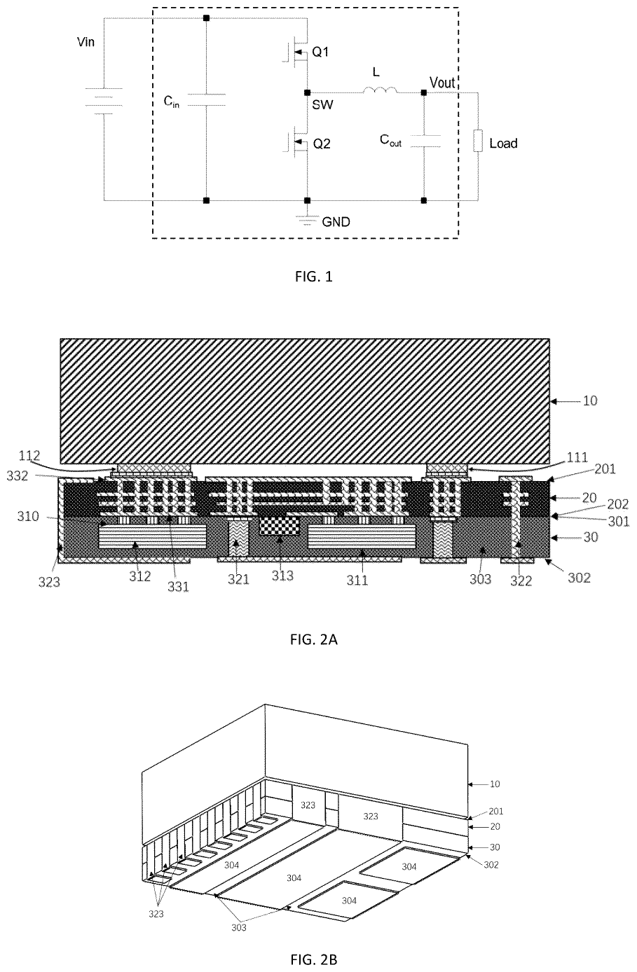

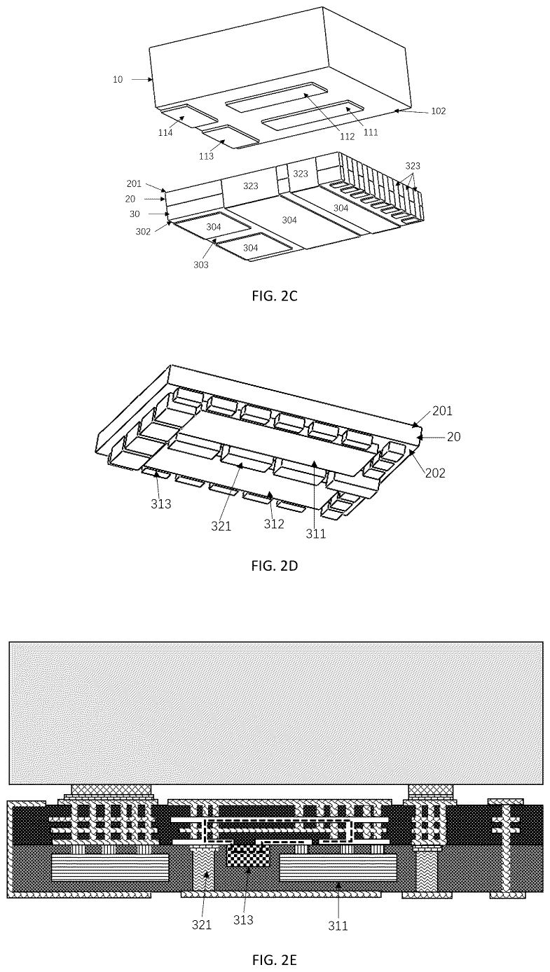

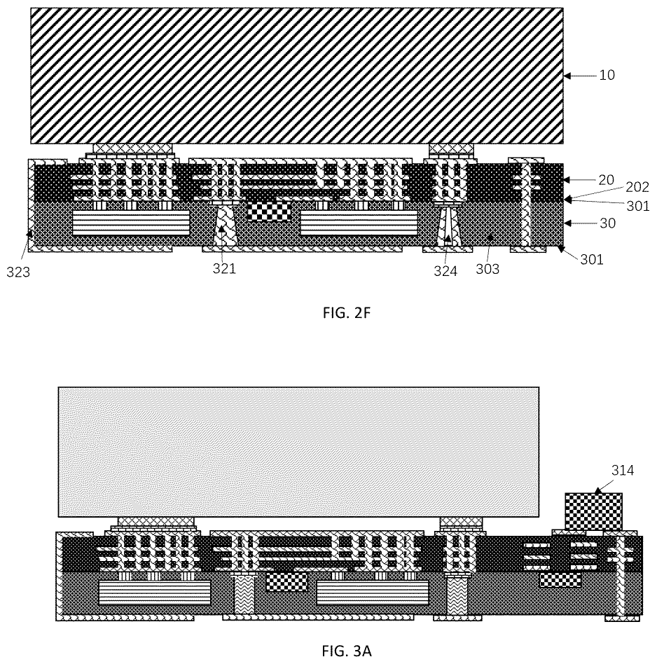

The power supply module (hereinafter referred to as a power supply module with a high heat dissipation and low parasitic inductance disclosed by the present application is applicable to a circuit topology comprising a magnetic assembly, a semiconductor switch device, an input capacitor and an output capacitor, and is not limited to a Buck circuit or a proportional conversion circuit. In the present application, the Buck circuit is used as an example for description, as shown in FIG. 1. The power supply module disclosed in the present application is shown in FIG. 2A to FIG. 2D, wherein FIG. 2A is a side cross-sectional view of the power supply module, FIG. 2B is a three-dimensional schematic diagram of the power supply module, FIG. 2C is an exploded schematic diagram of the power supply module, and FIG. 2D is a partial structural schematic diagram of the power supply module. As shown in FIG. 2A, the power supply module comprises a magnetic assembly 10, a substrate 20 and an element layer 30. The substrate 20 comprise an upper surface 201 and a lower surface 202 opposite to each other, an inner wiring layer and a conductive hole. Both the upper surface 201 and the lower surface 202 of the substrate 20 are provided with a metal wiring layer, and the metal wiring layer of the upper surface and the metal wiring layer on the lower surface are electrically connected by means of the inner wiring layer and the conductive hole. The element layer 30 comprises an upper surface 301 and a lower surface 302 opposite to each other, wherein the lower surface 202 of the substrate 20 and the upper surface 301 of the element layer 30 are disposed adjacent to each other. Winding pins of the magnetic assembly 10 are fixed and electrically connected to a metal wiring layer provided on the upper surface 201 of the substrate 20. The element layer 30 further comprises an insulator 303, power chips 311 and 312 (i.e., the semiconductor switching device in FIG. 1), a capacitor 313 and connectors 321, 322, 323. The power chips 311 and 312, and the capacitor 313 are all arranged adjacent to the upper surface 301 of the element layer 30; pins of the power chips 311 and 312, and the capacitor 313 are all fixed and electrically connected to the metal wiring layer on the lower surface 201 of the substrate. The lower surface 302 of the element layer 30 is provided with a surface metal wiring layer, and the connection mode between the substrate wiring and the surface metal wiring layer can be implemented by using the connector; the connectors 321 and 322 both penetrate the upper surface 301 and the lower surface 302 of the element layer 30; the connector 321 is realized by means of the via; the connector 322 is connected to the lower surface 202 of the substrate 20 by means of disposing prefabricated copper, and electrically connected to the lower surface 202 of the substrate by means of the bonding material; and electrically connected to the metal wiring layers by means of a metallization process. The connector 323 employs an plating edge, and the plating edge is disposed on a side of the element layer 30 and the substrate 20, and wrapped a part of the upper surface 201 of the substrate 20, a partial side surface of the element layer 30, a partial side surface of the substrate 20, and a part of the lower surface 302 of the element layer 30; the connectors are used for realizing the electrical connection between the metal wiring layer on the lower surface 302 and the metal wiring layer on the lower surface 202 or the upper surface 201. The connector 322 uses a prefabricated copper block, and the prefabricated copper block has the characteristic of low impedance; the via of the connector 321 is highly flexible in its configuration; and the plate edge metallization of the connector 323 has the characteristic of saving the size of the horizontal space. Therefore, in the power supply module, the connector can use any one or any combination of 321, 322, and 323 according to requirements.

In the present embodiment, the power chips 311 and 312 use planar power devices, and in each power chip, the two planar power devices are electrically connected in series, and the series connection point is an electrical common end 331, the electrical common end 331 is provided on the lower surface 202 of the substrate 20. Similarly, the upper surface 201 of the substrate 20 is also provided with an electrical common end 332, and the electrical common ends 331 and 332 are electrically connected to the conductive holes by means of an internal wiring layer and a conductive hole provided in the substrate 20. A winding pin 112 of the magnetic assembly 10 is fixed and electrically connected to the electrical common end 332. The projection of the winding pin 112 of the magnetic assembly and the projection of the power chip 312 on the same horizontal plane at least partially overlap. Each power chip comprises a functional surface 310, and the chip pin of the power chip is disposed on the functional surface 310. The electrical common end 331 of the surface of the power chip and the winding pin 112 of the magnetic core assembly are vertically interconnected by means of an inner wiring layer and a via hole provided in the substrate 20, and the connecting material is a highly thermally conductive material such as copper. Therefore, the power chip has excellent upward thermal resistance. In this embodiment, the capacitor 313 is an input capacitor Cin, and is electrically connected in parallel with two planar power devices connected in series.

Referring to FIG. 2B to FIG. 2D, a surface metal wiring layer 304 is provided on the lower surface 302 of the element layer 30 for being fixed and electrically connected to an external assembly or system board; a side edge of the substrate 20 and a side edge of the element layer are provided with the connector 323. The winding pins 111, 112, 113 and 114 of the magnetic assembly are disposed on the lower surface 102 of the magnetic assembly 10.

In this embodiment, the following production process can be used:
Step 1: preparing a substrate 20;
Step 2: mounting an element (such as a power chip 311, 312, a capacitor 313 or a copper block 321) on a second surface 202 of the substrate 20;
Step 3: plastic packaging the second surface 202 of the substrate 20 and the element provided on the second surface 202 to form an insulator 303;
Step 4: disposing a surface metal wiring layer 304 on a surface of the insulator 303.

Preferably, between step 3 and step 4, when the connector 322 is formed by means of drilling and electroplating or the plate edge metallization to form the connector 323, a corresponding drilling or grooving step needs to be added; or when a copper block is used to form the connector 321, a window is opened for the prefabricated copper block; and then step 4 is performed.

The connector 321 can be any one or more of an input positive connector, an output positive connector and a grounding connector, and the connector 321 is used for transmitting a power signal. The partial connector 323 is configured to transmit a control signal, a sampling signal, a monitoring signal, or the like.

In the present embodiment, the electrical common end of the power chip is disposed adjacent to the magnetic assembly, and the electrical common end is connected to the winding pins of the magnetic assembly, so that the power chip can dissipate heat by means of the magnetic assembly or the winding, and the power chip has a good thermal resistance to the direction of the magnetic assembly; on the other hand, the electrical common end of the power chip is a switching signal, and the electrical common end is provided on the upper surface 301 of the element layer 30 away from the system board, thereby avoiding the influence or interference of the switching signal on the system board. Further, compared with a conventional embedded process in a chip, the number of wiring layers of the substrate is not limited, and the selection of the power chip is more flexible (the capacitor with copper terminals is not required); moreover, the number of power chips is not limited, and the structure can be used for one to hundreds of power chips, and the same technical effect can be obtained; the heights of the power chip, the capacitor, etc. do not need to be matched, and devices with different heights can be made by using the same process flow, and also have the same technical effect.

Referring to the dashed line in FIG. 2E, in this embodiment, a laminated wire is used inside the substrate 20, and two ends of the integrated capacitor 313 (i.e., the input capacitor Cin) are electrically connected to the connector 321 and the power chip 311 by means of the laminated wires, such that the input circuit is shown in a dashed line in FIG. 2E, further reducing the loop inductance in the input circuit. The capacitor 313 and the connector 321 in FIG. 2E are horizontally arranged. In other embodiments, the capacitor 313 and the connector 321 can also be arranged in the direction perpendicular to the paper surface, thereby further reducing the width of the horizontal direction of the power supply module. FIG. 2F shows another implementation of the connector; for example, the connector 321 is a blind hole structure, and the connector 324 is a blind hole structure filled with a leveling medium. The processing process of the connector 324 comprises the following steps: firstly, drilling holes in the element layer, performing hole edge electroplating, then filling the holes with glue, leveling the glue after curing, and then performing surface metallization processing to form a surface wiring layer; the use of a blind hole for filling a leveling medium is applicable to the application of a solid hole that cannot be plated when the thickness of the element layer is large, and the depth of the blind hole is too deep to electroplate and form a filled via; compared with the manner of providing a metal column, the implementation mode is more flexible, the occupied space is relatively small, and the process is simple.

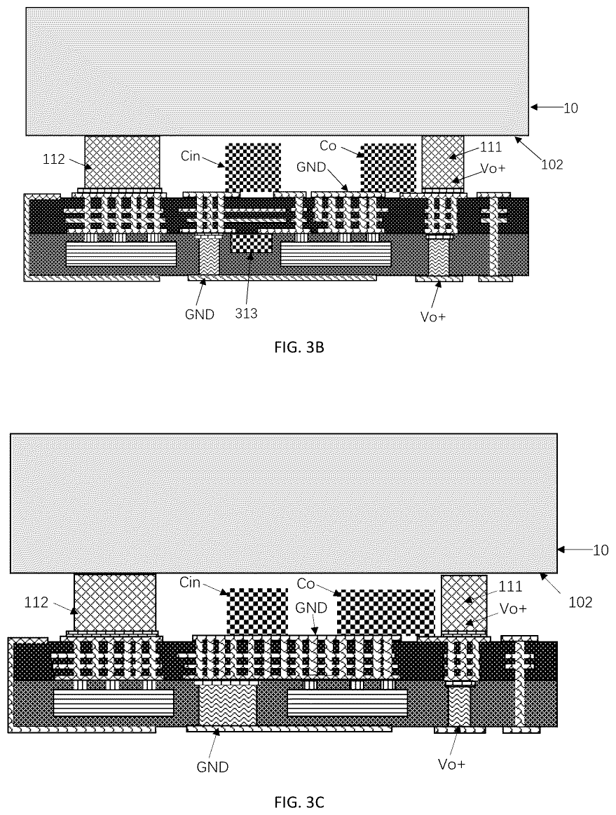

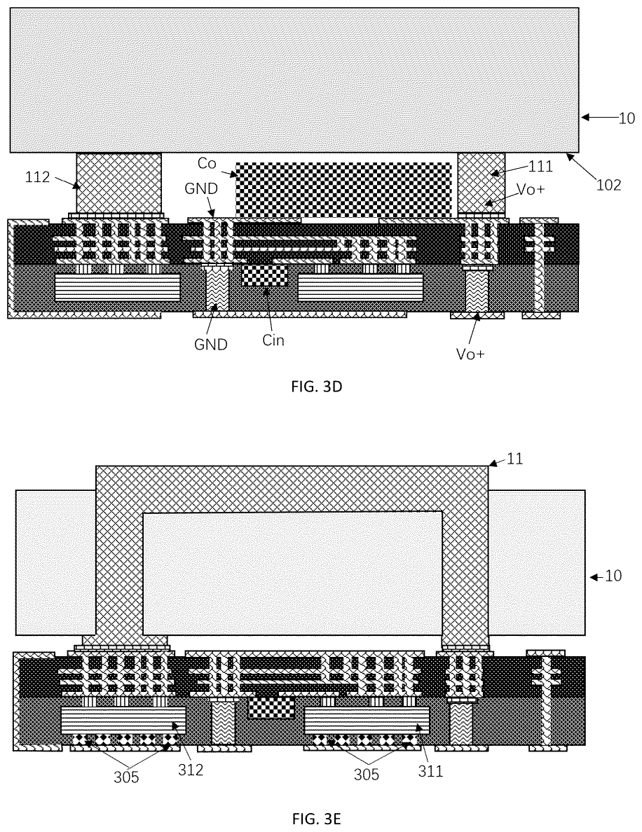

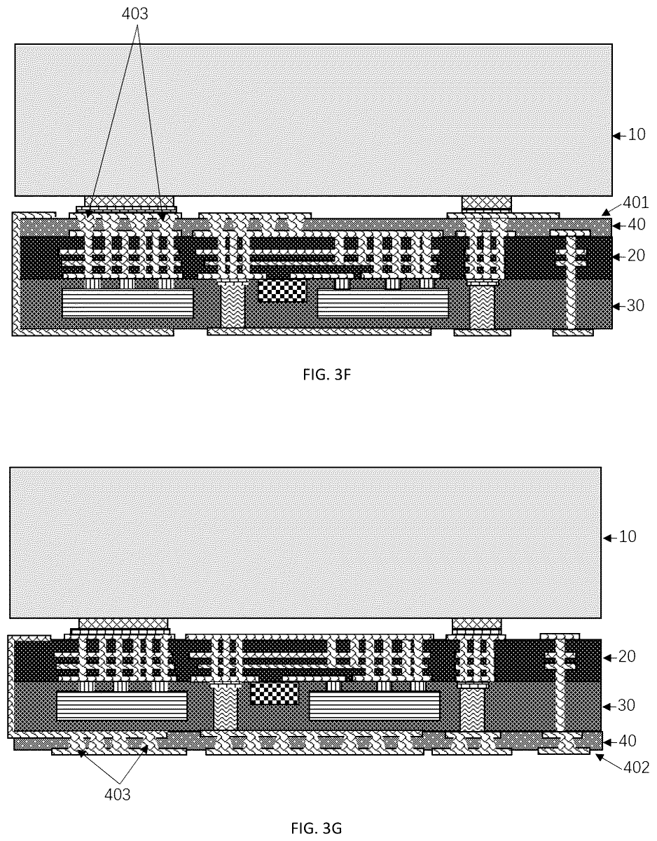

FIG. 3A to FIG. 3G show an expanded embodiment. In the embodiment shown in FIG. 3A, the size of the magnetic assembly 10 is less than the size of the substrate 20. Therefore, on the substrate, the region not covered by the magnetic assembly 10 may be provided with other elements 314, thereby further improving the integration level of the power supply module.

In the embodiment shown in FIG. 3B to FIG. 3D, the winding pins of the magnetic assembly are protruded from the lower surface of the magnetic assembly. In FIG. 3B, an accommodation space is formed between the lower surface 102 of the magnetic assembly 10 and the upper surface 201 of the substrate 20; more elements may be provided on the upper surface 201 of the substrate 20, for example, the input capacitor Cin and/or the output capacitor Co, or the resistor, capacitor or controller that required for the other peripheral circuits. In the embodiment of FIG. 3C, an input capacitor Cin and an output capacitor Co are disposed on the upper surface 201 of the substrate 20, and the negative terminal GND of the input capacitor Cin and the output capacitor Co is disposed on the copper laying on the same physical connection. By means of the shortest distance between the negative terminal of the input capacitor Cin and the negative terminal of the output capacitor Co, the conducted interference caused by switching transients can be effectively isolated. In the embodiment shown in FIG. 3D, the upper surface 201 of the substrate 20 is provided with an output capacitor Co, and the lower surface 202 of the substrate 20 is provided with an input capacitor Cin (in other embodiments, the upper surface 201 may also be provided with an input capacitor Cin, the lower surface 202 is provided with an output capacitor Co), the projection of the copper laying disposing on the upper surface or the lower surface of the substrate 20 and connecting to the negative electrode GND of the input capacitor Cin and the output capacitor Co on the same horizontal plane are at least partially overlaps; the copper laying disposing on the upper surface or the lower surface of the substrate 20 is vertically connected in a nearest path nearby through the via, so that the minimum interconnection distance of the ground wire is realized, and the external conduction interference of the switching signal can be effectively isolated.

In the embodiment shown in FIG. 3E, a heat dissipation via or a heat dissipation groove 305 is provided between the non-functional surface of the power chip 311 and 312 and the surface metal wiring layer of the lower surface 302 of the element layer 30. The heat dissipation via or the heat dissipation groove 305 is copper plated or the like having extremely high thermal conductivity, and may also be a high thermal conductivity paste, etc., thereby providing a smaller downward thermal resistance for the power chip. The winding 11 of the magnetic assembly can pass through the upper surface of the magnetic core and are exposed on the upper surface of the magnetic core, provide a smaller upward thermal resistance for the power chip, and further enhance the heat dissipation capability of the power supply module.

In the embodiment shown in FIG. 3F and FIG. 3G, a dielectric layer 40 is laminated. In FIG. 3F, in addition to the prefabricated part (i.e., the substrate 20 and the wiring layer inside the substrate 20), the substrate can also be pressed the dielectric layer 40 on the upper surface 201 of the substrate 20 and disposing the outer wiring layer on the upper surface 401 of the dielectric layer 40; the outer wiring layer, and the surface layer of the prefabricated part of the substrate are connected by means of the via 403. In this way, more complex wiring can be achieved. Furthermore, the outer wiring layer on the upper surface 401 of the dielectric layer 40 and the surface metal wiring layer on the lower surface 302 of the insulator 303 can simultaneously perform processes such as graphic definition processing, thereby simplifying the manufacturing process as a whole. In the embodiment shown in FIG. 3G, a dielectric layer 40 is laminated on the lower surface 302 of the element layer 30, an outer wiring layer is provided on the lower surface 402 of the dielectric layer 40, a surface metal wiring layer and an outer wiring layer on the lower surface 302 of the element layer 30 are connected by means of a via 403, etc. and the dielectric layer may also be a multi-layer wiring layer for increasing the current capability, and the lead-out position of the electrodes can be reallocated.

The embodiments of the present application and the technical features in the extended embodiments can be selected and combined in the same power supply module according to actual requirements, and all have the technical effects corresponding to the original embodiments.

The switch tube disclosed by the application can be used for realizing the functions of the switch disclosed by the application, such as a Si MOSFET [symbol] SiC MOSFET [symbol] GaN MOSFET or IGBT MOSFET.

The power supply module according to the embodiment can be an independent module or a part of the power supply module, and can meet the technical features and advantages disclosed by the application.

The “equal” or “same” or “equal to” disclosed by the application needs to consider the parameter distribution of engineering, and the error distribution is within +/−30%; and the included angle between the two line segments or the two straight lines is less than or equal to 45 degrees; the included angle between the two line segments or the two straight lines is within the range of [60, 120]; and the definition of the phase error phase also needs to consider the parameter distribution of the engineering, and the error distribution of the phase error degree is within +/−30%.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A power supply module, comprising:
a substrate, a magnetic assembly, and an element layer;
wherein the element layer comprises an insulator, at least one power chip, a capacitor, a connector, and an upper surface and a lower surface opposite to each other;
the substrate comprises an upper surface and a lower surface opposite to each other; the substrate further comprises metal wiring layers, and the metal wiring layers are provided on the upper surface and the lower surface of the substrate;
the magnetic assembly is provided on the upper surface of the substrate, and winding pins of the magnetic assembly are electrically connected to the metal wiring layer on the upper surface of the substrate;
the at least one power chip comprises a functional surface;
wherein at least two planar power devices connected in series are integrated on the functional surface, and the series node is an electrical common end; the functional surface of the power chip is provided with a chip pin; the power chip is provided on the lower surface of the substrate, and the chip pin is electrically connected to the metal wiring layer on the lower surface of the substrate; the winding pins of the magnetic assembly are electrically connected to the electrical common end;
projections of the winding pins of the magnetic assembly and the power chip on the same horizontal plane at least partially overlap;
the capacitor is arranged on the lower surface of the substrate, and the capacitor is connected in parallel with two planar power devices connected in series;
the insulator covers at least a portion of a lower surface of the substrate, the power chip, and the capacitor, the upper surface of the element layer is disposed adjacent to the lower surface of the substrate, the lower surface of the element layer is provided with a surface metal wiring layer, and the connector electrically connects the metal wiring layer of the substrate and the surface metal wiring layer on the lower surface of the element layer.

2. The power supply module of claim 1, wherein the connector penetrates through the upper surface and the lower surface of the element layer, and the connector is a via or a copper block.

3. The power supply module of claim 1, wherein a side surface of the substrate and a side surface of the element layer are metallized to form a connector, and the connector covers a part of the upper surface of the substrate, a part of the side surfaces of the substrate and the element layer, and a part of the lower surface of the element layer.

4. The power supply module of claim 1, wherein the connector adopts a blind hole structure.

5. The power supply module of claim 1, wherein a size of the magnetic assembly in a horizontal direction is less than a size of the substrate in a horizontal direction; and other component is provided in an area of that the magnetic assembly does not cover the substrate.

6. The power supply module of claim 1, wherein winding pins of the magnetic assembly protrudes from the lower surface of the magnetic assembly; an accommodating space exists among the lower surface of the magnetic assembly, the upper surface of the substrate and winding pins of the magnetic assembly for accommodating an input capacitor and/or an output capacitor.

7. The power supply module of claim 6, wherein the input capacitor and the output capacitor are arranged in the accommodating space, and the negative electrodes of the input capacitor and the output capacitor are arranged on copper laying on the same layer.

8. The power supply module of claim 6, wherein the upper surface of the substrate is provided with one of the input capacitor and the output capacitor, and the lower surface of the substrate is provided with the other of the input capacitor and the output capacitor;
the negative electrodes of the input capacitor and the output capacitor are on the copper laying on the upper surface and the lower surface of the substrate, and projections of the copper layings disposing on the lower surface and the upper surface on the same horizontal plane at least partially overlap, and are connected by means of vias.

9. The power supply module of claim 1, wherein a heat dissipation via or a heat dissipation groove is provided between the non-functional surface of the power chip and the lower surface of the element layer.

10. The power supply module of claim 1, wherein a winding of the magnetic assembly is at least partially exposed on the upper surface of the magnetic assembly.

11. The power supply module of claim 1, further comprising:
a dielectric layer and an outer wiring layer, wherein the dielectric layer is disposed between the upper surface of the substrate and the lower surface of the magnetic assembly, and the outer wiring layer is disposed between the dielectric layer and the magnetic assembly;
the outer wiring layer is electrically connected to the metal wiring layer on the upper surface of the substrate through a via.

12. The power supply module of claim 11, wherein the outer wiring layer and the surface metal wiring layer on the lower surface of the element layer are completed in a same process.

13. The power supply module of claim 1, wherein a dielectric layer and an outer wiring layer are disposed on the lower surface of the element layer, and the outer wiring layer is disposed on a lower surface of the dielectric layer; and the outer wiring layer is electrically connected to the surface metal wiring layer on the lower surface of the element layer through a via.
